(19) United States
(12) Patent Application Publication
(10) Pub. No.: US 2024/0055283 A1
(43) Pub. Date: Feb. 15, 2024

(54) SUBSTRATE PROCESSING SYSTEM AND ITS CONTROL METHOD

(71) Applicant: CANON KABUSHIKI KAISHA, Tokyo (JP)

(72) Inventors: TAICHI YOSHIOKA, Tochigi (JP); NOBUYUKI KAWABATA, Tochigi (JP); KENJI IKEDA, Tochigi (JP); MASATO ANZAI, Tochigi (JP); JUN KITAGAWA, Tochigi (JP); TASUKU SUZUKI, Tochigi (JP)

(21) Appl. No.: 18/496,015

(22) Filed: Oct. 27, 2023

Related U.S. Application Data
(63) Continuation of application No. PCT/JP2022/015969, filed on Mar. 30, 2022.

(30) Foreign Application Priority Data
Jun. 3, 2021 (JP) 2021-093509

(51) Int. Cl. H01L 21/67; H01L 21/027; G05B 19/29

(52) U.S. Cl. CPC H01L 21/67253; H01L 21/67259; H01L 21/0274; G05B 19/29; G05B 2219/45031

(57) ABSTRACT

A substrate processing system includes a substrate processing apparatus, an input/output apparatus, a first control apparatus installed with first software, configured to control the substrate processing apparatus based on a first signal output from the input/output apparatus, and configured to acquire a second signal output from the substrate processing apparatus, a second control apparatus installed with second software, and configured to perform same calculation processing as that of the first control apparatus, and not configured to control the substrate processing apparatus, a first distributor configured to distribute the first signal to the second control apparatus, and a second distributor configured to distribute the second signal to the second control apparatus. The second control apparatus outputs a third signal based on the first signal and the second signal.

### CROSS-REFERENCE TO RELATED APPLICATIONS

This application is a Continuation of International Patent Application No. PCT/JP2022/015969, filed on Mar. 30, 2022, which claims the benefit of Japanese Patent Application No. 2021-093509, filed on Jun. 3, 2021, both of which are hereby incorporated by reference herein in their entirety.

### BACKGROUND

### Technical Field

One of the aspects of the embodiments relates to a substrate processing system and its control method.

### Description of Related Art

Software for controlling a lithography apparatus (substrate processing apparatus) needs to be improved as needed for higher accuracy and higher functionality. Further, software improvements are frequently made not only to newly developed lithography apparatuses but also to currently operating lithography apparatuses to add new functions and improve hardware performance. Thus, in updating software for the currently operating lithography apparatus, the software may not properly work and the update of the software has to be stopped.

On the other hand, it is difficult to test whether software can be updated using a simulator, etc. in advance, because it is necessary to obtain environmental information (configuration, data, operating conditions) equivalent to that of the operating apparatus. In addition, although it is possible to maintain quality by verifying data and accuracy after the software of the operating lithography system is updated, this method needs to use the user's lithography system for a long period of time.

Japanese Patent Laid-Open No. 2019-066692 discloses a lithographic system that shortens the downtime of the lithography apparatus by providing the lithography apparatus with another control apparatus that performs the same processing as the control apparatus and a simulation apparatus. Japanese Patent Laid-Open No. 2020-052812 discloses an engineering system that executes software debugging more suitable to the actual usage environment by uploading actual user data to the cloud.

In the lithographic system disclosed in Japanese Patent Laid-Open No. 2019-066692, the control apparatus that controls the lithography apparatus and the control apparatus that controls the simulation apparatus perform the same processing, but input data input to each control apparatus is not guaranteed to be the same and have different timings. The engineering system disclosed in Japanese Patent Laid-Open No. 2020-052812 performs software debugging using a virtual device that performs simulation on the cloud based on uploaded actual data, so testing cannot be performed using the same input data and timing. Therefore, errors in the input information between the actual environment and the simulation environment may cause differences in the conditions of the tests performed in advance, and the functions of the updated software may not operate normally.

### SUMMARY

A substrate processing system according to one aspect of the embodiment includes a substrate processing apparatus, an input/output apparatus, a first control apparatus installed with first software, configured to control the substrate processing apparatus based on a first signal output from the input/output apparatus, and configured to acquire a second signal output from the substrate processing apparatus, a second control apparatus installed with second software, and configured to perform same calculation processing as that of the first control apparatus, and not configured to control the substrate processing apparatus, a first distributor configured to distribute the first signal to the second control apparatus, and a second distributor configured to distribute the second signal to the second control apparatus. The second control apparatus outputs a third signal based on the first signal and the second signal.

Further features of the disclosure will become apparent from the following description of embodiments with reference to the attached drawings.

### BRIEF DESCRIPTION OF THE DRAWINGS

FIG. 1 is a configuration diagram of a substrate processing apparatus according to this embodiment.

FIG. 2 is a configuration diagram of a substrate processing system according to this embodiment.

FIG. 3 is a configuration diagram of a control apparatus according to this embodiment.

FIG. 4 is a flowchart illustrating processing of the control apparatus according to this embodiment.

### DESCRIPTION OF THE EMBODIMENTS

A detailed description will now be given of embodiments according to the present invention will be described with reference to the drawings.

This embodiment will describe an exposure apparatus that exposes a pattern onto a substrate via a mask as an example of a lithography apparatus (substrate processing apparatus) that forms a pattern on a substrate, but this embodiment is applicable to another substrate processing apparatus. For example, this embodiment can also be applied to a substrate processing apparatus such as an imprint apparatus that forms a pattern of an imprint material onto a substrate using a mold, or a drawing apparatus that forms a pattern on a substrate by irradiating a substrate with a charged particle beam. This embodiment can also be applied to a substrate processing apparatus such as a coating apparatus that applies a photosensitive medium onto the surface of a substrate and a developing apparatus that develops a photosensitive medium on which a pattern has been transferred. In addition, this embodiment can also be applied to substrate processing apparatus such as a film forming apparatus (CVD apparatus, etc.), a processing apparatus (laser processing apparatus, etc.), an inspection apparatus (overlay inspection apparatus, etc.), and a measurement apparatus (mark measurement apparatus, etc.).

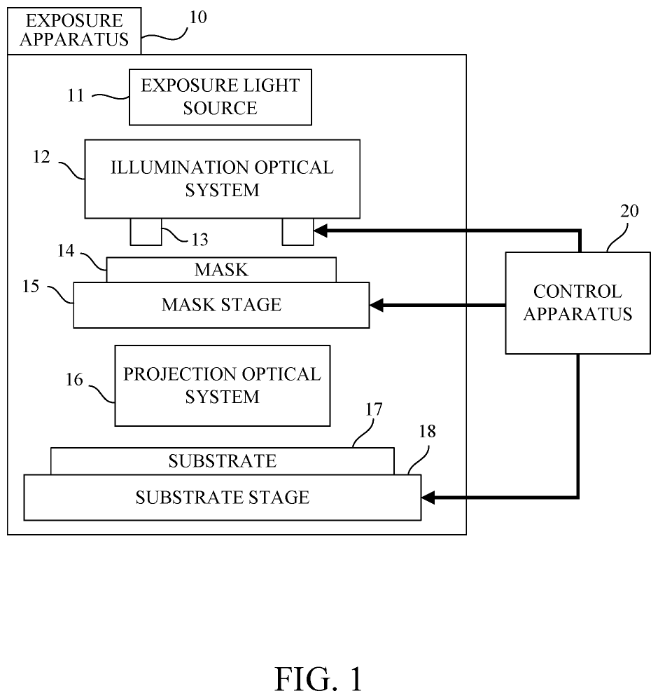

Referring now to FIG. 1, a description will be given of an exposure apparatus (substrate processing apparatus) 10 according to this embodiment. FIG. 1 is a configuration diagram of the exposure apparatus 10. The exposure apparatus 10 includes an exposure light source 11, an illumination optical system 12, a measurement camera 13, a mask stage 15, a projection optical system 16, and a substrate stage 18. A mask 14 is mounted on the mask stage 15 and a substrate 17 is mounted on the substrate stage 18. The control apparatus 20 controls the measurement camera 13, the mask stage 15, and the substrate stage 18 of the exposure apparatus 10. The exposure apparatus 10 exposes a pattern drawn on the mask 14 onto the substrate 17 via the projection optical system 16. At this time, the control apparatus 20 needs to accurately align the pattern on the substrate 17 on which the pattern is already formed with the pattern on the mask 14. Thus, the exposure processing is performed while the positional shift between the patterns measured by the measurement camera 13 is controlled with the mask stage 15 or the substrate stage 18 on a two-dimensional plane of XYθ.

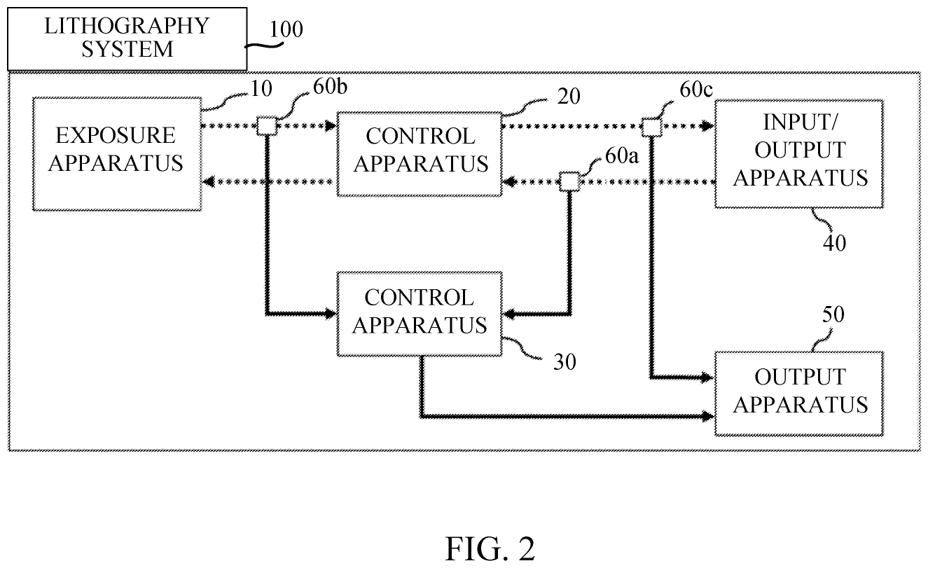

Referring now to FIG. 2, a description will be given of a lithography system (substrate processing system) 100 according to this embodiment. FIG. 2 is a block diagram of the lithography system 100.

The lithography system 100 includes the exposure apparatus 10, the control apparatus (first control apparatus, control unit) 20 that controls the exposure apparatus 10, a control apparatus (second control apparatus) 30 that performs the same calculation processing as that of the control apparatus 20, and an input/output apparatus 40 that inputs/outputs information to/from the control apparatus 20. The lithography system 100 further includes a distributor (first distributor) 60a and a distributor (second distributor) 60b. The distributor 60a transmits (distributes) input information (first signal) from the input/output apparatus 40 to the control apparatus 30. The distributor 60b transmits (distributes) output information (second signal) from the exposure apparatus 10 to the control apparatus 30. The lithography system 100 further includes an output apparatus 50 that processes data (third signal) output from the control apparatus 30, and a distributor (third distributor) 60c that distributes data (fourth signal) output from the control apparatus 20 to the input/output apparatus 40 and the output apparatus 50.

The control apparatus 20 receives operation information from the input/output apparatus 40 and a control result of the exposure apparatus 10, and outputs a control command for controlling the exposure apparatus 10 and display information to be displayed on the input/output apparatus 40. The control apparatus 30 receives operation information from the input/output apparatus 40 and a control result of the exposure apparatus 10, and outputs a control command for controlling the exposure apparatus 10 and display information to be displayed on the output apparatus 50. Although the exposure apparatus 10 is controlled according to the control command output from the control apparatus 20, the control command output from the control apparatus 30 is not input to the exposure apparatus 10. That is, the control apparatus 30 performs the same calculation processing as that of the control apparatus 20, but the exposure apparatus 10 is not actually controlled by the control command from the control apparatus 30.

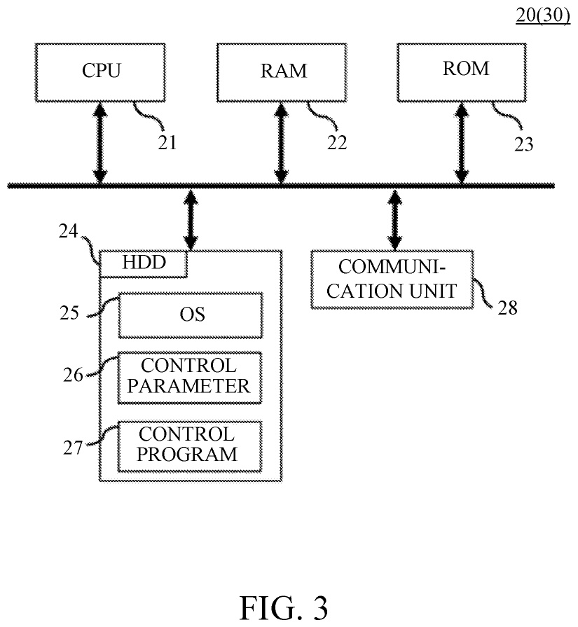

Referring now to FIG. 3, a description will be given of the hardware configurations of the control apparatuses 20 and 30 according to this embodiment. FIG. 3 is a configuration diagram of the control apparatuses 20 and 30. The control apparatuses 20 and 30 each have the same configurations.

Each of the control apparatuses 20 and 30 includes a computer apparatus such as a personal computer or a workstation. A CPU 21 is a central processing unit that controls each of the control apparatuses 20 and 30 as a whole. A RAM 22 is a memory functioning as a main memory. A ROM 23 is a memory that stores a boot program and data. A HDD 24 is a hard disk drive and contains an operating system 25, a control parameter 26, and a control program (control software) 27. The control parameter 26 is a parameter for exposure, and includes driving amounts of the mask stage 15 and the substrate stage 18, and the like. The control program 27 is programmed to behave according to the control parameter 26. Also, the control program 27 may be updated to improve the performance of the exposure apparatus 10. This embodiment will refer to an old, pre-update control program (old software) as a first control program (first software), and an updated control program (updated software) as a second control program (second software).

In a case where the control apparatus 20 controls the exposure apparatus 10, the control apparatus 20 issues a control instruction (control command) to the exposure apparatus 10 using the control program 27 that runs on the operating system 25. A communication unit 28 includes an interface for communicating with the distributors 60a and 60b, and performs input/output to and from the distributors 60a and 60b. The control apparatuses 20 and 30 may operate on the same hardware.

The input/output apparatus 40 is a device for displaying according to the operation of the exposure apparatus 10 and display information from the control apparatus 20. The input/output apparatus 40 is an operation terminal provided in a host computer, the exposure apparatus 10, or the like. The output apparatus 50 is a device for displaying information according to display information from the control apparatus 30. The output apparatus 50 is an operation terminal provided in a host computer, the exposure apparatus 10, or the like. The output apparatus 50 may be the same as the input/output apparatus 40. Further, the output apparatus 50 can compare the processing result of the control apparatus 20 and the processing result of the control apparatus 30 distributed by the distributor 60c and display the comparison result.

The distributors 60a and 60b are devices for broadcasting (distributing) operation information from the input/output apparatus 40 and the control result from the exposure apparatus 10 to the control apparatuses 20 and 30. The distributor 60c is a device for distributing data output from the control apparatus 20 to the input/output apparatus 40 and the output apparatus 50. The distributors 60a, 60b, and 60c are network hubs, for example. Broadcasting can be realized, for example, by connecting the control apparatuses 20 and 30 and a network hub with a LAN cable. Thereby, the control apparatuses 20 and 30 can acquire the same data at the same timing via the communication unit 28. Further, the distributors 60a and 60b may start broadcasting in a case where the control program 27 of the control apparatus 30 is updated.

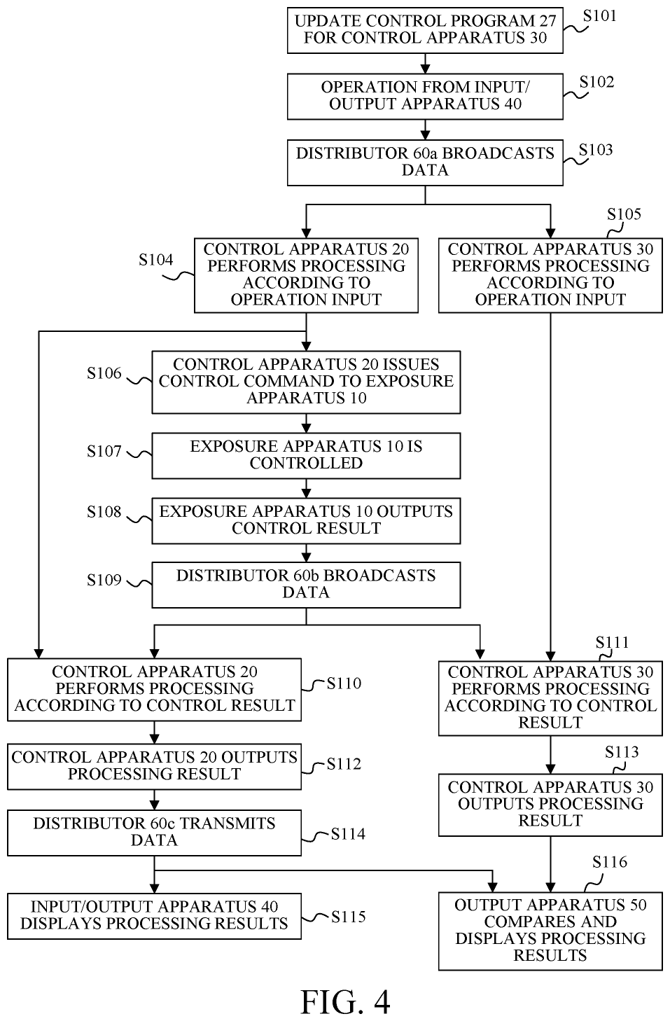

Referring now to FIG. 4, a description will now be given of the processing of the control apparatuses 20 and 30 in the lithography system 100, that is, the method of broadcasting the operation information from the input/output apparatus 40 to the control apparatuses 20 and 30 and comparing the output data. FIG. 4 is a flowchart illustrating the processing of the control apparatuses 20 and 30.

First, in step S101, the control apparatus 30 reads a new control program from the outside of the control apparatus 30 and updates the control program 27 of the control apparatus 30. The new control program is generally stored in a recording medium such as a magneto-optical disk and provided by the manufacturer of the exposure apparatus 10, but is not limited to this example. The control program 27 may be updated to a new control program via a network such as the Internet.

Next, in step S102, the user inputs operation information via the input/output apparatus 40 (operation input). The operation information is generally input via the operation terminal provided in the exposure apparatus 10. Next, in step S103, the distributor 60a broadcasts the operation information from the input/output apparatus 40 to the control apparatuses 20 and 30. Next, in steps S104 and S105, the control apparatuses 20 and 30 start processing according to the operation input at the same timing.

Next, in step S106, the control apparatus 20 outputs a control command to the exposure apparatus 10. On the other hand, since the control apparatus 30 does not actually control the exposure apparatus 10, it does not output a control command. Next, in step S107, the exposure apparatus 10 performs processing according to the control command output from the control apparatus 20 in step S106 (controlled according to the control command). Next, in step S108, the exposure apparatus 10 outputs the control result. Next, in step S109, the distributor 60b broadcasts the control result output from the exposure apparatus 10 to the control apparatuses 20 and 30. Next, in steps S110 and S111, the control apparatuses 20 and 30 start processing according to the control result at the same timing.

Next, in steps S112 and S113, the control apparatuses 20 and 30 output the processing results to the input/output apparatus 40 and the output apparatus 50. Next, in step S114, the distributor 60c transmits the processing result from the control apparatus 20 to the input/output apparatus 40 and the output apparatus 50. Next, in step S115, the input/output apparatus 40 displays the processing result. In step S116, the output apparatus 50 compares the processing result of the control apparatus 20 and the processing result of the control apparatus 30, and displays the comparison result.

Here, for example, the output apparatus 50 determines whether a difference between the output of the control apparatus 20 and the output of the control apparatus 30 coincides with an expected difference. Since inputs are made to the control apparatuses 20 and 30 by broadcasting, there is no output difference due to operating conditions, and only an output difference depends on the processing of the control program 27. In a case where the comparison result in the output apparatus 50 is the expected difference, it is considered that the processing of the new control program is reasonable and the software can be normally updated. Therefore, it is determined that the control apparatus 20 can read a new control program from the outside of the control apparatus 20 and the control program 27 can be updated. In a case where the comparison result by the output apparatus 50 does not coincide with the expected difference, it is determined that at least one of the new control program and the control parameter needs to be modified.

As an example, in order to solve the phenomenon that the vibration of the substrate stage 18 affects the exposure result, the permissible range of the vibration of the substrate stage 18 (vibration standard determination) may be changed (for example, narrowed). This is because the substrate stage 18 has a large number of control parameters 26 and the values of the control parameters 26 significantly differ depending on the exposure apparatus 10. Thus, the effect of updating the new control program differs depending on the lithography system 100.

As another example, in order to improve the alignment accuracy between the pattern on the substrate 17 and the pattern on the mask 14, along with the update to the new control program, the method for calculating the positional shift of the pattern measured by the measurement camera 13 may be changed. The pattern on the substrate 17 and the pattern on the mask 14 are different depending on the user's production process. Therefore, the effect of updating the new control program differs depending on the production process.

In other words, in these examples, updating the new control program may not produce the expected result. Depending on the circumstances, an error may occur and the operation may become impossible, and the operation rate of the exposure apparatus 10 may drop, or the accuracy may drop and defects may occur.

Accordingly, in this embodiment, the new control program is stored and saved in the recording medium of the magneto-optical disc. The control apparatus 30 updates the control program 27 of the control apparatus 30 by reading the magneto-optical disc. Then, an exposure operation is performed from the operation terminal provided in the lithography system 100. At this time, the control parameters 26 of the control apparatuses 20 and 30 are assumed to be the same as those at which the phenomenon occurred.

In a case where the exposure ends, the control result output from the exposure apparatus 10 is broadcasted (distributed) to the control apparatuses 20 and 30 by the distributor 60b, and the control apparatuses 20 and 30 perform processing. The processing result of the control apparatus 20 is transmitted to the output apparatus 50 by the distributor 60c. Therefore, the output apparatus 50 can compare the processing result of the control apparatus 20 and the output result of the control apparatus 30.

The control apparatus 20 performs processing with the pre-update control program 27, but the control apparatus 30 performs processing with the post-update control program (new control program) 27. Therefore, in a case where the output apparatus 50 compares the processing results, for example, a difference in the standard determination result of the vibration of the substrate stage 18 and a difference in the pattern positional shift result are output.

These differences indicate that the processing of the new control program is reasonable, and it can be determined that the control program 27 of the control apparatus 20 that actually controls the exposure apparatus 10 can be normally updated. Further, for example, if no difference is found as a comparison result of the processing results, the new control program is not valid and therefore needs to be modified or the control parameters 26 need to be changed. Alternatively, it is determined that the new control program cannot be used for this model of the lithography system 100 or for this user's production process. At this time, since the control apparatus 20 performs processing with the pre-update control program 27 and controls the exposure apparatus 10 for production, no problems do not occur, such as an error causing the exposure apparatus 10 to be inoperable, the operation rate drop of the exposure apparatus 10, and the accuracy drop causing defects.

As described above, the substrate processing system (lithography system 100) includes the substrate processing apparatus (exposure apparatus 10), the input/output apparatus 40, the first control apparatus (control apparatus 20), the second control apparatus (control apparatus 30), the first distributor (distributor 60a), and the second distributor (distributor 60b). The first control apparatus is installed with first software (pre-update control program), controls the substrate processing apparatus based on a first signal output from the input/output apparatus, and acquires a second signal output from the substrate processing apparatus. The second control apparatus is installed with second software (updated control program), performs the same calculation processing as that of the first control apparatus, but does not control the substrate processing apparatus. The first distributor distributes the first signal to the second control apparatus. The second distributor distributes the second signal to the second control apparatus. The second control apparatus outputs a third signal based on the first signal and the second signal.

The substrate processing system may have the output apparatus 50 and the third distributor (distributor 60c). The output apparatus obtains a third signal from the second control apparatus. The third distributor distributes to the output apparatus the fourth signal output from the first control apparatus to the input/output apparatus based on the second signal.

The output apparatus may display data corresponding to the third signal and data corresponding to the fourth signal. The user can compare the data corresponding to the third signal and the data corresponding to the fourth signal displayed on the output apparatus and determine whether or not to update the software.

The output apparatus may compare the data corresponding to the third signal and the data corresponding to the fourth signal. The user can determine whether or not to update the software based on the comparison result by the output apparatus.

The output apparatus may determine whether or not to update the first software installed in the first control apparatus to the second software based on the difference between the data corresponding to the third signal and the data corresponding to the fourth signal. According to this configuration, the output apparatus can determine whether or not to update the software. The difference between the data corresponding to the third signal and the data corresponding to the fourth signal may occur along with a change in the permissible range of vibration of the substrate stage or a change in the positional shift calculation method between the pattern of the substrate and the pattern of the mask associated with the software update.

### <Embodiment of Article Manufacturing Method>

An article manufacturing method according to this embodiment is suitable to manufacture articles such as microdevices such as semiconductor devices, elements having fine structures, and flat panel displays. The article manufacturing method according to this embodiment includes the steps of processing a substrate using the substrate processing system (lithography system 100) described above and manufacturing an article from the substrate processed in this processing. Further, such manufacturing methods may include well-known steps (exposure, oxidation, film formation, vapor deposition, doping, planarization, etching, resist stripping, dicing, bonding, packaging, etc.). The article manufacturing method according to this embodiment is beneficial to at least one of the article performance, quality, productivity, and production cost in comparison with the conventional methods.

This embodiment can provide a substrate processing system, a control apparatus, a control method for the substrate processing system, and an article manufacturing method, which can previously determine whether or not an update software function normally works.

While the disclosure has been described with reference to embodiments, it is to be understood that the disclosure is not limited to the disclosed embodiments. The scope of the following claims is to be accorded the broadest interpretation so as to encompass all such modifications and equivalent structures and functions.

What is claimed is:

1. A substrate processing system comprising:
a substrate processing apparatus;
an input/output apparatus;
a first control apparatus installed with first software, configured to control the substrate processing apparatus based on a first signal output from the input/output apparatus, and configured to acquire a second signal output from the substrate processing apparatus;
a second control apparatus installed with second software, and configured to perform same calculation processing as that of the first control apparatus, and not configured to control the substrate processing apparatus;
a first distributor configured to distribute the first signal to the second control apparatus; and
a second distributor configured to distribute the second signal to the second control apparatus,
wherein the second control apparatus outputs a third signal based on the first signal and the second signal.

2. The substrate processing system according to claim 1, wherein the second software is software obtained by updating the first software.

3. The substrate processing system according to claim 1, further comprising:
an output apparatus configured to acquire the third signal from the second control apparatus; and
a third distributor configured to distribute to the output apparatus a fourth signal output from the first control apparatus to the input/output apparatus based on the second signal.

4. The substrate processing system according to claim 3, wherein the output apparatus displays data corresponding to the third signal and data corresponding to the fourth signal.

5. The substrate processing system according to claim 3, wherein the output apparatus compares data corresponding to the third signal with data corresponding to the fourth signal.

6. The substrate processing system according to claim 3, wherein the output apparatus determines whether or not to update the first software installed in the first control apparatus to the second software based on a difference between data corresponding to the third signal and data corresponding to the fourth signal.

7. The substrate processing system according to claim 6, wherein the difference between the data corresponding to the third signal and the data corresponding to the fourth signal is caused by a change in the permissible range of vibration of the substrate stage accompanying the update of the first software to the second software.

8. The substrate processing system according to claim 6, wherein the difference between the data corresponding to the third signal and the data corresponding to the fourth signal is generated by changing a position shift calculating method of a pattern of a substrate and a pattern of a mask associated with the update of the first software to the second software.

9. The substrate processing system according to claim 1, wherein the first control apparatus and the second control apparatus operate on the same hardware.

10. A control apparatus configured to perform same calculation processing as that of a control unit installed with first software, configured to control a substrate processing apparatus based on a first signal output from an input/output apparatus, and configured to acquire a second signal output from the substrate processing apparatus, the control apparatus being not configured to control the substrate processing apparatus,
wherein the control apparatus is installed with second software, and
wherein the control apparatus outputs a third signal based on the first signal distributed by a first distributor and the second signal distributed by a second distributor.

11. A control method of a substrate processing system, the control method comprising the steps of:
outputting a first signal from an input/output apparatus to a first control apparatus installed with the first software;
distributing through a first distributor the first signal to a second control apparatus installed with second software;
controlling through the first control apparatus a substrate processing apparatus based on the first signal;
performing same calculation processing as that of the first control apparatus through the second control apparatus based on the first signal, the second control apparatus being not configured to control the substrate processing apparatus;
outputting a second signal from the substrate processing apparatus to the first control apparatus;
distributing the second signal to the second control apparatus by a second distributor; and
outputting a third signal from the second control apparatus based on the first signal and the second signal.

12. The control method of the substrate processing system according to claim 11, further comprising the step of updating the first software installed in the second control apparatus to the second software before the step of outputting the first signal is performed.

13. An article manufacturing method comprising the steps of:
processing a substrate using the substrate processing system according to claim 1; and
manufacturing an article from a processed substrate.
